(19) United States
(12) Patent Application Publication
(10) Pub. No.: US 2019/0072854 A1
(43) Pub. Date: Mar. 7, 2019

(54) METHOD AND APPARATUS FOR PROCESSING A LITHOGRAPHIC PRINTING PLATE

(71) Applicant: AGFA NV, Mortsel (BE)

(72) Inventors: Philippe MORIAME, Mortsel (BE); Iris BOGUNOVIC, Mortsel (BE); Jan SINNESAEL, Mortsel (BE)

(21) Appl. No.: 16/084,252

(22) PCT Filed: Feb. 3, 2017
(86) PCT No.: PCT/EP2017/052413

§ 371 Date: Sep. 12, 2018

(30) Foreign Application Priority Data
Mar. 16, 2016 (EP) 16160576.1
Mar. 16, 2016 (EP) 16160591.0
Mar. 16, 2016 (EP) 16160616.5
Mar. 16, 2016 (EP) 16160627.2
May 10, 2016 (EP) 16168969.0

(51) Int. Cl. G03F 7/32; B41N 3/08; G03F 7/039; G03F 7/30; G03F 7/11

(52) U.S. Cl. CPC G03F 7/322; B41N 3/08; G03F 7/11; G03F 7/3071; G03F 7/3092; G03F 7/039

(57) ABSTRACT

A method for processing a lithographic printing plate material includes treating the plate material with an alkaline development solution, and treating the plate material with an aqueous liquid whereby the aqueous liquid is sprayed to both the front side and the backside of the plate material.

### CROSS REFERENCE TO RELATED APPLICATIONS

This application is a 371 National Stage Application of PCT/EP2017/052413, filed Feb. 3, 2017. This application claims the benefit of European Application No. 16160576.1, filed Mar. 16, 2016, European Application No. 16160591.0, filed on Mar. 16, 2016, European Application No. 16160616.5, filed on Mar. 16, 2016, European Application No. 16160627.2, filed on Mar. 16, 2016 and European Application No. 16168969.0, filed on May 10, 2016, which are incorporated by reference herein in their entirety.

### BACKGROUND OF THE INVENTION

### 1. Field of the Invention

The present invention relates to a method and apparatus for processing lithographic printing plate precursors with a reduced consumption of processing liquids.

### 2. Description of the Related Art

Lithographic printing typically involves the use of a so-called printing master such as a printing plate which is mounted on a cylinder of a rotary printing press. The master carries a lithographic image on its surface and a print is obtained by applying ink to said image and then transferring the ink from the master onto a receiver material, which is typically paper. In conventional lithographic printing, ink as well as an aqueous fountain solution (also called dampening liquid) are supplied to the lithographic image which consists of oleophilic (or hydrophobic, i.e. ink-accepting, water-repelling) areas as well as hydrophilic (or oleophobic, i.e. water-accepting, ink-repelling) areas. These areas can also be referred to as printing and non-printing areas respectively or as image and non-image areas respectively. In so-called driographic printing, the lithographic image consists of ink-accepting and ink-adhesive (ink-repelling) areas and during driographic printing, only ink is supplied to the master.

Lithographic printing masters are generally obtained by the image-wise exposure and processing of a printing plate precursor (also referred to hereafter as “plate material”), which contains a heat- or light-sensitive coating on a substrate. The coating of the plate material is exposed image-wise to heat or light, typically by means of a digitally modulated exposure device such as a laser, which triggers a (physico-)chemical process, such as ablation, polymerization, insolubilization by cross-linking of a polymer or by particle coagulation of a thermoplastic polymer latex, solubilization by the destruction of intermolecular interactions or by increasing the penetrability of a development barrier layer. Although some plate materials are capable of producing a lithographic image immediately after exposure, the most popular plate materials require wet processing with a developer since the exposure produces a difference of solubility or of rate of dissolution in a developer between the exposed and the non-exposed areas of the coating. In positive-working plate materials, the exposed areas of the coating dissolve in the developer while the non-exposed areas remain resistant to the developer. In negative-working plate materials, the non-exposed areas of the coating dissolve in the developer while the exposed areas remain resistant to the developer. Most plate materials contain a hydrophobic coating on a hydrophilic substrate, so that the areas which remain resistant to the developer define the ink-accepting, printing areas of the plate while the hydrophilic substrate is revealed by the dissolution of the coating in the developer at the non-printing areas.

Conventionally, a plate material is developed by immersing it in a developer as it passes through the processing apparatus. Typically the material is also subjected to mechanical rubbing with e.g. one or more rotating brushes or specified roller(s)—after a while or after being treated with the developer.

An important trend in lithographic platemaking is related to ecology and sustainability. Systems and methods which enable a low consumption of processing liquids such as developer, rinse water and gum solution, or which allow processing with aqueous developers comprising no hazardous chemicals and/or which have a pH close to 7 (neutral developer), have attracted a lot of attention in the marketplace. A convenient method which has become popular involves the use of a gum solution as developer, whereby the plate material is developed and gummed in a single. Such methods however can only be used for specially designed plate materials, which have lithographic coatings that are sufficiently soluble or dispersible in the gum solution so that a good clean-out (complete removal of the coating at non-printing areas of the image) is obtained.

During processing the developer becomes loaded with components of the coating that have been removed during development and the amount of material in the developer increases as more plates are developed. Due to the increasing amount of dissolved material in the developer, the activity of the developer decreases resulting in a reduced ability of removing the non-printing areas of the lithographic image. Due to this exhaustion of the developer, the lithographic properties of the printing plates change in time, which is typically compensated by regenerating the development solution of the processing apparatus with fresh developer or with a replenishment solution. The term “fresh developer” refers to the developer that is used when filling the processing apparatus, typically after a restart (which typically involves draining the exhausted developer, cleaning the apparatus and refilling the apparatus with fresh developer). The term “replenishment solution” defines a solution used to control the activity level of the development solution. Replenishment solutions typically have a higher alkalinity and/or blocker (image protecting agent) concentration compared to the development solution.

Another cause of degradation of the developer activity is the pH decrease caused by carbon dioxide in the atmosphere which dissolves into the development solution as the time passes. The latter accounts for about 70% of the regeneration required in the developing process. In order to reduce the amount of this time-dependent regeneration, a development system that does not depend on the alkaline component (i.e. the pH level) of the development solution has been proposed. Then it is generally necessary to add to the development solution some alternative agent, capable of dissolving the non-printing areas of the image, as replacement of the alkaline component, e.g. an organic solvent. However, the most suitable organic solvents are volatile organic compounds, and their use is therefore problematic, because it causes pollution and health hazards when released into the atmosphere or into water.

In conventional processing methods, a wet film of the alkaline developer liquid is present on the coating when the plate leaves the developer; this film needs to be removed in a water rinse step to avoid attack of the lithographic image by the highly alkaline developer. However, as this water rinsing step is typically a spraying step onto the surface of the plate material, and the developing step is typically a dipping step, alkaline developing solution may still be present at the back side of the plate which implies health risks for the person who handles the processed plate, oxidation of the aluminum support, and/or contamination of the finishing gum.

After the development and the water rinse steps, the plate is typically gummed, which is sometimes also called finished or desensitized. Gumming involves the application of a protective coating on the lithographic image, especially the non-printing areas, to avoid contamination or oxidation of the aluminum substrate. A gum solution typically contains protective compounds (surfactants) or “gum” as referred to in this application and is typically also applied by spraying onto the surface of the plate as it forms a protective layer which preserves the lithographic image - a typical gum solution forms a protective coating which preserves the lithographic image. The backside of the plate is consequently not protected by a gum layer and contamination and/or oxidation of the aluminum substrate may occur.

After the development of the plates, they may be stacked and/or handled by the printer before they are feeded to a printing machine. During this handling acts, scratches may be formed on the surface of both sides of the plate, due to relative movement of two consecutive plates. Scratches or scuffs can also occur when plates are removed from the stack. Scratches in the image and non-image areas at the front side of the plate often produce visible defects on prints. It is therefore highly desirable to provide a convenient solution to sufficiently protect lithographic images against contamination and/or mechanical damaging.

### SUMMARY OF THE INVENTION

Preferred embodiments of the present invention provide a solution which enables safe handling of processed printing plates and/or which reduces the risk of contamination e.g. by oxidation, fingerprints, fats, oils or dust, and/or damaging e.g. by scratches during handling of these plates.

These advantages and benefits have been achieved by the method for processing a lithographic printing material as defined below which has the specific feature that the plate material is treated with an aqueous liquid at the backside of its support, and the processing apparatus as defined in below. A preferred embodiment of the processing apparatus of the present invention is described in more detail below.

According to the present invention there is also provided a lithographic printing plate as defined in claim 14 which has the specific feature that the plate contains a hydrophilic layer including a gum solution at the backside of its support.

Other features, elements, steps, characteristics and advantages of the present invention will become more apparent from the following detailed description of preferred embodiments of the present invention. Specific embodiments of the invention are also defined in the dependent claims.

### BRIEF DESCRIPTION OF THE DRAWINGS

FIG. 1 is a schematic representation of a preferred embodiment of the development unit of the apparatus of the invention, shown as it is filled with developer and gum solution.

FIG. 2a is a more detailed representation of the development cavity viewed along the processing direction.

FIG. 2b is a more detailed representation of the development cavity viewed along the direction which is perpendicular to the processing direction.

FIGS. 3a and 3b are schematic representations of protruding elements (ribs) provided on the bottom plate of the development cavity.

FIG. 4 is a schematic cross-section of suitable shapes of protruding elements.

The numbers in the Figures refer to the following features of a preferred development section of the apparatus according to the present invention:
1 development section
2 gumming section
3 first gumming unit
4 second gumming unit
5 development unit
6 development cavity
7 cover plate
8 entry aperture
9 exit aperture
10 bottom plate including a first part (10A), a second part (10B) and a bend (10C)
11 roller pairs: 11A and 11B (development section); 11C, 11D, 11E and 11F (gumming section); and 11G (drying section).
12 development solution
13 scavenger rollers
14 brush
15 spray bars 15A and 15B, 15C, 15D and 15E
16 first gum sump 16A and second gum sump 16B
17 cascade overflow
18 drain
19 drying section
20 protruding element
21 sidewall
22 sidewall
23 processing direction
24 drying means
25 first gum solution
26 second gum solution

### DETAILED DESCRIPTION OF THE PREFERRED EMBODIMENTS

### Definitions

Front side of a printing plate material or printing plate: side which carries respectively a heat-sensitive coating or a lithographic image.

Backside of a printing plate material or printing plate: side opposite to the front side; i.e. the side which does not carry a heat-sensitive coating or lithographic image.

Development section: part of an apparatus which comprises a development unit, a developer recirculation system and preferably a developer regeneration system.

Gumming section: part of an apparatus which comprises a gumming unit, and preferably also a gum recirculation system and a gum regeneration system.

Development unit: vessel designed to hold development solution optionally including nip rollers.

Fresh (development or gumming) solution: solution which has not yet been used for processing a plate material.

Gumming unit: vessel designed to hold gum solution optionally including nip rollers, scavenger rollers, brush(es) and/or means for supplying gum solution to the plate.

(Re)circulation system: system comprising the necessary pipes and pump(s) to generate a flow of developer or gum solution.

Regeneration system: system comprising the necessary pipes and pump(s) to supply regenerator liquid to a development unit or a gumming unit.

Replenishment solution: regenerator liquid used to control the activity level of the development solution or the gum solution.

(Re)start: the process of draining developer from the development unit followed by refilling the development unit with fresh developer (the latter step taken alone is referred to as “start”).

Unless otherwise indicated, parameter values of a solution, e.g. pH, density, viscosity, conductivity, etc. are always measured at 25° C.

### Development

According to the current invention, an exposed printing plate material is developed by means of a suitable alkaline developer, also referred to as herein as “development solution” or “development liquid”. In the development step, the non-printing areas of the coating of the plate material are at least partially removed without substantially removing the printing areas.

Development of a plate material is typically performed in a vessel containing development solution (i.e. development unit), for example by dipping or immersing the plate in the developer, or by (spin-)coating, spraying and/or pouring developer onto the plate. The treatment with development solution may be combined with mechanical rubbing, e.g. by one, two or more rotating brushes and/or specified rollers e.g. Molton rollers. As most preferred embodiment, the development is carried out by the apparatus described hereafter. Preferably, the plate is not brushed during the treatment with alkaline development solution. During the development step, any water-soluble protective layer on top of the image-recording layer, if present, is preferably also removed.

During processing, the development solution becomes loaded with components of the coating that have been removed by the development and the amount of material in the development solution increases as more plates are developed. Due to this increasing amount of material in the development solution, the activity of the development solution typically decreases which may result in a reduced ability to remove the non-printing areas of the lithographic image and/or a reduced ability to maintain the removed components in solution or in a dispersed state. In addition, the pH of the development solution may decrease due to the dissolution of carbon dioxide from the air into the development solution as the time passes. Therefore, the development solution is preferably shielded from the air by a cover plate.

In a preferred embodiment, a low amount (as defined below) of development solution is used during a period of about one week or more, more preferably about two weeks or more, during which a plurality of plates is processed with the same development solution, either with or without regeneration. After that period, the development unit is reloaded with fresh development solution. This process is preferably fully automatic, which means that the development solution is preferably automatically drained from the development unit and that the development unit is preferably automatically refilled with fresh developer by means of a system including a supply tank including fresh development solution, a waste tank for collecting the exhausted developer and the necessary pipes and pumps. The fresh development solution may be produced automatically inside the processing apparatus by diluting a more concentrated solution with water.

Because the development solution is used during just a limited period of time, only a negligible amount of sludge—such as salted-out compounds, precipitated or flocculated ingredients and/or other undissolved compounds—may be formed during the processing period between two (re)starts. Also, the level of dissolved ingredients and/or compounds present in the developing solution may be limited; i.e. the development solution is not exhausted. As a result, not only the maintenance of the development unit (as described below) becomes less burdensome, but also deposit on the exit and/or other rollers, and/or build-up on heater elements in the developer unit is limited as well as possible adherence of sludge on the printing plate which may impair the images formed thereon; e.g. accept ink in the non-image areas.

The preferred development unit described below is especially suited to enable to use a relatively small volume of development solution during a limited period of time between two (re)starts. In the context of this invention, a low amount of development solution refers to for example a volume below 50 1 e.g. between 1 and 20 1, preferably between 2 and 15 1, more preferably between 5 and 12 1 and most preferably between 8 and 10 1. The volume refers to the amount of development solution present in the development unit, i.e. excluding the volume that may be present in the regeneration system, in the recirculation system and in any supply and waste collector tanks. Said volume is dependent on the width of the development unit (which is typically between 0.5 m and 2.0 m), as explained below.

Preferably, the development solution is reloaded after one week of processing and/or after processing of for example 400 m² of precursor. Preferably, the reloading of the development solution is automated.

Alternatively, the development quality may be kept constant for a longer period, so that a restart can be postponed for a longer time, for example more than one month, preferably more than two months, more preferably more than four months and most preferably more than six months. In this embodiment, a low volume of development solution as well as high volume of development solution may be used; however, a high volume of development solution is preferred, for example a volume between 5 and 200 1, preferably between 20 and 150 1, more preferably between 40 and 100 1 and most preferably between 60 and 90 1. As above, the actual amount depends on the width of the development unit.

The volume of the development solution in the development unit is preferably in the range Vmin to Vmax, which both depend on the width of the development unit according to the following formulae :

Vmax=[B+(W/0.95 m)]·liter (formula 1)

Vmin=[1+(W/0.95 m)]·liter (formula 2)

wherein B represents an integer from 6 to 17 and wherein W is the width, expressed in meter and measured perpendicularly to the processing direction of the largest plate material that can be processed in the development unit (wherein the “processing direction” is defined as the path in the development unit along which the plate material travels during the treatment with development solution). Preferably B represents 6, 7, 8, 9 to 13, 14, 15, 16 or 17.

### Regeneration of Development Solution

The activity level of the development solution may be maintained during its working period by adding replenishment solution. Depending on the concentration of the mentioned regenerator liquids, the rate of regeneration may be between 1 ml and 100 ml per m² of treated plate material, preferably between 2 ml/m² and 85 ml/m², 4 ml/m² and 60 ml/m², more preferably between 5 ml/m² and 30 ml/m².

It has been found that by using small amounts of developer for a limited period in time, little replenishment is required to keep the activity of the developer at a sufficient level and/or constant. Therefore, the embodiment wherein a small volume of developer is used generates, compared to development of the prior art where large amounts of developer for a longer period in time are used, less waste. Indeed, the waste—including the amount of drained developer and the amount of applied replenisher—generated during said limited period in time, is less compared to the waste that would have been generated when the development would have been carried out during a longer period in time.

In addition, the volume of development solution is preferably kept constant by for example adding water and/or development solution; also referred to in the art as top-up the development solution solution.

The mentioned regenerator liquids can be added continuously or in batches when the activity of the development solution becomes too low and/or to keep the activity level constant. The activity level of the development solution can be determined by monitoring e.g. pH, density, viscosity, conductivity, the number and/or area (square meters) of processed plates processed since a (re)start with fresh solution and/or the time lapsed since a (re)start with fresh solution. When the addition of regenerator is regulated by measurement of one of these parameters, for example the conductivity of the development solution, the regenerator liquid can be added when a predetermined threshold value of that parameter is reached or is crossed. The amount of regenerator added each time depends on the predetermined threshold value. For example, when the measured parameter is the number of square meters of plate material processed, a predetermined amount of replenishment is added each time after processing a predetermined area of plate material. As a further example, the measured parameter can be the conductivity or conductivity increase of the solution monitored with a conductivity meter. Beyond a conductivity value, regenerator can automatically be added to the development solution.

The development unit preferably contains an overflow pipe which drains the development solution into a collector tank. The drained development solution may be purified and/or regenerated by e.g. filtration, decantation or centrifugation and then reused, however, the drained development solution is preferably collected for disposal.

### Recirculation of Development Solution

The development solution present in the development unit may be at least partly (re)circulated, e.g. by means of a (re)circulation pump. (Re)circulation means that a flow of development solution is generated within the development unit, preferably producing sufficient turbulence to enhance the removal of non-printing areas from the coating of the plate and/or to homogenize the development solution present in the development unit. At least a part of the development solution may be recirculated, i.e. conveyed along a closed loop, e.g. from a sump of the development unit into one or more inlet openings which inject or jet the developer solution back into the development unit. During recirculation, the development solution is preferably at least partly removed (sucked in) from the development unit and then injected or jetted back into the development unit (or cavity, see further), thereby circulating and stirring the development solution. The development solution is jetted or injected in the development unit via at least one inlet opening which is capable of jetting said development solution into the development unit without (preferably almost no) air contact or in other words, whereby the jetted solution is (substantially) not in contact with air. By limiting and/or avoiding air contact during recirculation of the development solution, degradation of the developer activity for example caused by carbon dioxide present in the atmosphere and/or evaporation is substantially reduced or even avoided. As a result, the amount of replenishment solution required to regenerate the development solution is substantially reduced. Also, addition of e.g. water and/or replenishment solution in order to keep the volume of development solution constant, is highly reduced. As a result, the amount of waste liquids generated by the processing process of the present invention is highly reduced.

### Development Solution

Unless otherwise indicated, the amounts of developer ingredients given herein refer to the fresh developer as used for a (re)start. Such fresh developer may be obtained as a ready-to-use solution or by diluting a more concentrated solution that is supplied by the manufacturer with water, e.g. a dilution between 2 and 10 times. The dilution of a developer concentrate may be done in a separate apparatus or may be integrated in the processing apparatus. As a result, the preferred embodiments of this invention allow to develop plates with good clean-out by using less than 100 ml/m2 of such concentrated solution, preferably less than 50 ml/m2, more preferably less than 25 ml/m2, and most preferably from 0.5 to 10 ml/m2 of such concentrated solution. Alternatively, 0.2 to 2 ml/m2 of developer is preferably used.

A preferred alkaline developer is an aqueous solution which has a pH of at least 10, more typically at least 12, preferably from 13 to 14. Preferred high pH developers comprise at least one alkali metal silicate, such as lithium silicate, sodium silicate, and/or potassium silicate. Sodium silicate and potassium silicate are preferred, and sodium silicate is most preferred. A mixture of alkali metal silicates may be used if desired. Especially preferred high pH developers comprise an alkali metal silicate having a SiO2 to M2O weight ratio of at least of at least 0.3, in which M is the alkali metal. Preferably, the ratio is from 0.3 to 1.2. More preferably, it is from 0.6 to 1.1, and most preferably, it is from 0.7 to 1.0. The amount of alkali metal silicate in the high pH developer is typically at least 20 g of SiO2 per 1000 g of developer (that is, at least 2 wt. %) and preferably from 20 g to 80 g of SiO2 per 1000 g of developer (2-8 wt. %). More preferably, it is 40 g to 65 g of SiO2 per 1000 g of developer (4-6.5 wt. %).

In addition to the alkali metal silicate, alkalinity can be provided by a suitable concentration of any suitable base, such as, for example, ammonium hydroxide, sodium hydroxide, lithium hydroxide, potassium hydroxide and/or organic amines, and/or mixtures thereof. A preferred base is sodium hydroxide. Further preferred examples of alkaline agents include organic alkaline agents such as monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine and pyridine. These alkaline agents may be used singly or in combination of two or more thereof. Preferred among these alkaline agents are sodium hydroxide, potassium hydroxide, trisodium phosphate, tripotassium phosphate, sodium carbonate and potassium carbonate.

Optional components of all the above mentioned developers are e.g. anionic, nonionic and/or amphoteric surfactants, biocides (antimicrobial and/or antifungal agents), antifoaming agents or chelating agents (such as alkali gluconates), solubilizers, image protecting agents such as blockers or retardants, dissolution inhibitors and thickening agents (water soluble or water dispersible polyhydroxy compounds such as glycerin or polyethylene glycol).

The development step is followed by a rinsing step and/or a gumming step.

### Rinsing

In a first embodiment of the present invention, after development of the plate material with an alkaline development solution, both the front side and the backside of the plate are rinsed with an aqueous liquid. The aqueous liquid is preferably water such as for example tap water or any water which may contain any chemicals at low concentration; for example minerals and/or metals such as Cu, Fe, Se, Cr or Ca. Alternatively, the aqueous liquid is a gum solution as described below.

The rinsing with the aqueous liquid is carried out by spraying at both the sides of the support i.e. the front side and the backside, whereby not only the wet film of the alkaline developer present on the lithographic image is removed, but also the alkaline developer present on the backside of the support. As a result, attack of the lithographic image and attack of the backside of the support by the highly alkaline developer, are substantially avoided.

In a preferred embodiment, the rinsing step is in cascade configuration wherein, in a first and a second rinsing unit, a first and second rinsing step are carried out respectively which are configured as a cascade whereby the second rinse solution overflows into the first rinsing unit.

The rinsing step is preferably followed by a gumming step which involves post-treatment of the lithographic printing plate with a gum solution.

### Gumming

A gum solution is typically an aqueous liquid which comprises one or more surface protective compounds that are capable of protecting the lithographic image of a printing plate against contamination or damaging. Suitable examples of such compounds are film-forming hydrophilic polymers or surfactants. The gum solution preferably has a pH below 10, more preferably below 9, even more preferably a pH from 0 to 8, and most preferably from 1 to 6. Suitable gum solutions used herein have a pH around 2, 5 or 7.

The plate precursor can, if required, be further post-treated with a suitable correcting agent or preservative as known in the art.

The gum solution is preferably applied at both the front side and the backside of the plate material, preferably by spraying. As a result, a gum layer remains on the plate after treatment with the gum solution. The dry coating weight of the layer that preferably remains on the front side and/or the backside of the plate after treatment with the gum solution preferably comprises between 0.01 and 20 g/m² of the surface protective compound. Alternatively, the dry coating weight is preferably between 0.02 and 5 g/m², more preferably between 0.03 and 1 g/m², and most preferably between 0.05 and 0.5 g/m².

The application of a protective layer also at the back of a printing plate has the major advantage that damages which may be caused by mechanical forces applied to the surface of the coating during automatic transport, mechanical handling and/or manual handling, are highly reduced or even eliminated.

### Preferred Embodiment: Cascade Configuration

In a preferred embodiment of the present invention, the development or the rinsing described above may be followed by at least two treatments with a gum solution, which is applied by means of a cascading gumming section comprising a first and a second gumming unit wherein a first and second gumming step are carried out respectively (also referred to as a “cascade configuration”). This gumming section is also referred to as the “gumming system”. At least one of said gumming treatments involves application of gum solution at both the front side and the backside of the plate material, preferably by spraying.

In the first gumming step, the processed plate is treated at the front side and/or the backside with a first gum solution. The main purpose of this treatment is to rinse and/or neutralize the plate, i.e. the removal of any developer from the front side and/or the backside of the plate, and to ensure good clean-out of the image, if not already obtained in the development unit. In the second gumming step, the plate material is subsequently treated with a second gum solution at the front side and/or the backside. The main purpose of the second step is to protect the lithographic image and/or the backside of the plate by the application of a gum layer as further discussed below. It shall be understood, however, that the said purpose of the first and second gumming steps is not a limitation of the present invention. For instance, also the second gum solution may contribute to the clean-out of the image, for those plate materials of which the non-printing areas of the coating are not completely removed after the first gumming step. Reduced clean-out usually results in toning (ink-acceptance in the non-image areas) of the printing plate and/or in ink build-up on the blanket.

The gum solutions are preferably brought into contact with the printing plate by spraying, jetting, immersing, dipping or by a coating technique, including spin coating, roll coating, slot coating or gravure coating. The use of spray bars is preferred. A spray bar production includes a hollow rod with a predetermined series of holes. The gumming unit(s) may also be provided with at least one roller for rubbing and/or brushing the plate while applying the gum to the coating.

The two gumming steps are carried out in two different gumming units configured as a cascade whereby the second gum solution overflows into the first gumming unit. Such a cascade configuration provides the advantage that sludge formation and/or contamination by for example carry-over of dissolved ingredients in the second gum solution is reduced, whereby an increase of the viscosity of the gum solution in the second gumming unit can be reduced or inhibited. This results in an improved lifetime of the gumming system as only the gum solution of the first gumming unit becomes loaded with contaminants from the dragged-out development solution, whereby the second gum solution can be used for gumming a higher number of plates so as to save costs and to enable a sustainable system.

During the use of the method with a cascade configuration, the compositions of the two gum solutions may be different, although the first gum solution originates from the second gum solution via the cascade overflow. The difference may be due to for example contamination by developer dragged out with the plate from the development unit into the first gumming unit and/or by further dissolution of non-printing areas of the coating if clean out is not fully achieved by the development, further combined with for example insufficient regeneration of the first gum solution by the cascade overflow. The latter problem may be solved by actively pumping gum solution—in addition to the cascade overflow—from the second to the first gumming unit.

### (Re)Circulation of Gum Solution

The first and/or second gum solutions are preferably (re)circulated, more preferably independently from one another. The first and second gum solutions are kept in respectively two baths or sumps from which they are recirculated into for example spray bars which supply the gum solution. The gum solutions then flow back into the respective sumps.

Preferably, a filter is present in the (re)circulation system, e.g. in the pipes, which is capable of removing any kind of sludge and/or dissolved ingredients from the gum solutions.

### Regeneration of Gum Solution

The gum solutions may be regenerated by adding water or a replenishment or a mixture thereof.

The above mentioned regenerator liquids may be added to the first and/or second gum solution. The amount of regenerator added to the first gum solution may be restricted so as to compensate only for the volume which is drained in the cascade and dragged out with the plates. The amount of regenerator added to the second gum solution is preferably adjusted to compensate for the degradation of the gum solution by the dragged-out developer and for the volume which is drained as waste.

It is preferred that the amount of replenishment added for the regeneration of gum solution, is small in order to limit the amount of waste produced during processing. Therefore, the rate of regeneration—depending on the concentration of the replenishment/gum solution—is preferably between 1 ml and 100 ml per m² of treated plates, more preferably between 2 ml/m² and 85 ml/m², more preferably between 4 ml/m² and 60 ml/m² and most preferably between 5 ml/m² and 30 ml/m².

The addition of regenerator, i.e. the type and the amount thereof, may be regulated by the measurement of for example the number and/or area of processed plates, the pH or pH change of the gum solution, the viscosity, the density, the time lapsed since the gumming system was loaded with fresh gum solution, or by monitoring the minimum and maximum volume in each gumming unit, or a combination of at least two of them.

The first gumming unit preferably contains an overflow pipe which drains the gum solution into a collector tank by overflow. The drained gum solution may be cleaned by e.g. filtration, decantation or centrifugation and then reused to regenerate the first and/or the second gum solution. Preferably however, the drained first gum solution is collected for disposal.

The composition of the gum solution refers to the fresh gum solution that is used for a (re)start. In the embodiment with a cascade configuration, preferably, the same gum solution is used for the (re)start in both units of the gumming section. In alternative embodiments, a (re)start may involve filling the first and second gumming unit with different gum solutions. The composition of the gum solution described herein refers to the fresh gum solution used in the second gumming unit. Such fresh gum solution may be obtained as a ready-to-use solution or by diluting a more concentrated solution that is supplied by the manufacturer. The dilution of a gum concentrate may be done in a separate apparatus or may be integrated in the processing apparatus.

Preferably, the second gum solution is reloaded after one week of processing and/or after processing for example 400 m² of precursor. Preferably, the reloading of the first and/or second gum solutions are automated.

Alternatively, the gum quality may be kept constant for a longer period, so that a restart can be postponed for a longer time, for example more than one month, preferably more than two months, more preferably more than four months and most preferably more than six months.

Suitable gum solutions, to be used as fresh gum solution in the present invention, are aqueous liquids which comprise one or more surface protective compounds that are capable of protecting the lithographic image of a printing plate against contamination, oxidation or damaging. Suitable examples of such compounds are film-forming hydrophilic polymers or surfactants. The layer that remains on the plate after treatment with the gum solution in the second gumming step and drying preferably comprises between 0.1 and 20 g/m² of the surface protective compound. This layer typically remains on the plate until the plate is mounted on the press and is removed by the ink and/or fountain when the press run has been started. The gum solutions preferably have a pH below 10, more preferably below 9, even more preferably a pH from 0 to 8, and most preferably from 1 to 6. Suitable gum solutions used herein have a pH around 2, 5 or 7.

A solution of a non-ionic surfactant can be added when the gum solution needs a higher concentration of a surfactant.

### Processing Apparatus

The present invention also provides an apparatus which is especially designed for performing the processing methods of the present invention.

The apparatus for processing a lithographic printing plate material including a front side with an imaging layer and a backside opposite to the front side, comprises a development unit and a unit including at least one nozzle capable of spraying an aqueous liquid to the front side of the plate material and at least one nozzle which is capable of spraying the aqueous liquid to the backside of the plate material.

The Figures represent a highly preferred embodiment of such a processing apparatus, which includes a development section (1) a rinsing and/or gumming section. The development section (1) preferably includes a development unit (5) comprising an essentially closed development cavity (6) comprising a cover plate (7), a bottom plate (10) and sidewalls (21,22).

Well known features which are preferably present in the development section of the apparatus but not shown in the Figures are: a feeder for delivering plates one by one to the development section; a regeneration system; supply tanks comprising fresh developer, fresh gum solution, or one or more replenishing solutions; waste collector tanks wherein exhausted developer or gum solution are drained; a water tank to dilute concentrated chemistry; and other conventional parts.

When the description below refers to the plate material which during the operation of the apparatus travels through the various sections, it is assumed that the plate is facing upwards, i.e. with the heat- or light-sensitive coating facing upwards (the other side of the plate is referred to as “backside”). However, embodiments wherein the plate is facing downwards are equally within the scope of the present invention.

### Preferred Processing Apparatus: Development Section

The development section (1) includes a development unit (5) which preferably comprises at least two roller pairs (11A, 11B)—also referred to as nip or feeder rollers—which convey the plates into and out of the development unit. The development unit preferably comprises a cover plate (7) to shield the development solution from the air.

Preferably, an entry roller pair (11A) feeds the plate into the development unit, more preferably into a development cavity (6) of the unit, which is an essentially closed volume defined by a bottom plate (10), a cover plate (7) and sidewalls (21,22). The cavity has an entry aperture (8) where the plate enters the cavity and an exit aperture (9) where the plate leaves the cavity. An exit roller pair (11B) preferably conveys the plate from the development section to the gumming section.

A rubber blade may be provided at the entry aperture to prevent air from flowing into the cavity. The development cavity is preferably completely filled with development solution without any air being present between the cover plate and the surface of the development solution. Preferably, the cover plate covering the development cavity is completely in contact with the liquid surface of the development solution so that any flow of air above the development solution—i.e. the flow of air from the entry aperture to the exit aperture—is cut off. The main function of the cover plate is to reduce possible degradation of the development solution by the absorption of carbon dioxide from the ambient air and/or evaporation of water, thereby allowing to reduce the rate of regeneration (if any). The cover plate may also extend beyond the entry or exit aperture, e.g. the cover plate may include arc-shaped curves or rectangular shapes which cover the upper peripheral surfaces of the nip rollers.

The volume of the development cavity is preferably as low as possible. Preferably the volume of the cavity is from 0.5 dm³ to 50 dm³; more preferably from 1 dm³ to 25 dm³ and most preferably from 2 to 10 dm³. In a preferred embodiment, the entry aperture (8) and exit aperature (9) are narrow slots which have an aspect ratio (height/width) of at least 10, more preferably at least 20. The height of the entry slot (8) is preferably between 2 and 5 times the thickness of the plate. The exit slot (9) is preferably more narrow, for example having a height only a few times (for example 2 to 3) bigger than the thickness of the plate.

The bottom plate (10) preferably includes at least two parts which are separated by an upward bend (10C) so that a first part of the bottom plate (10A) is oriented at an angle from 0.5° to 60° relative to a second part of the bottom plate (10B). More preferably, the angle is between 1° and 50°, more preferably between 5° and 45° and most preferably between 10° and 35° relative to the first part. The length (distance along the processing direction) of the first and/or second part of bottom plate is preferably adapted in order to obtain a smooth movement of the plate through the development cavity. Preferably, the first part (10A) has a length from 0 to 50 cm, more preferably from 1 to 30 cm and most preferred from 2 to 15 cm. The second part (10B) preferably has a length from 1 to 50 cm, more preferably from 2 to 30 cm and most preferably from 3 to 25 cm. Preferably, the upward bend is substantially perpendicular relative to the processing direction.

The surface of the bottom plate (10), which faces the inside of the development cavity, is preferably provided with one or more protruding elements (20), which maintain a distance between the backside of the plate and the bottom plate. Preferably, at least two protruding elements are present, more preferably at least three protruding elements are present and most preferably at least four protruding elements are present. As a result, formation of scratches at the backside of the plates is reduced and a smooth transport of the plate through the cavity is obtained. In addition, the protruding surface of the bottom plate may prevent contact between the plate and sludge such as salted-out compounds, precipitated or flocculated ingredients which are collected between the protruding elements.

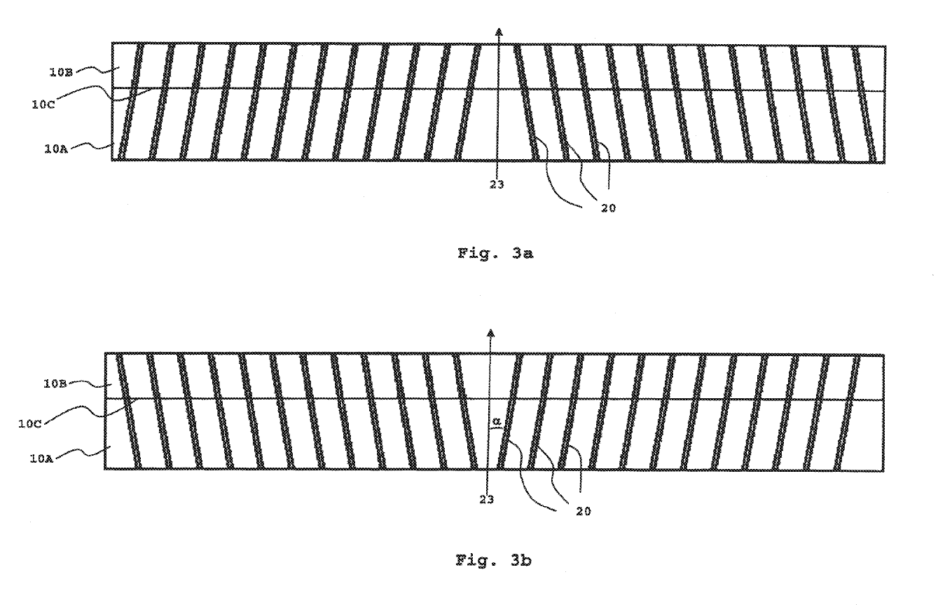

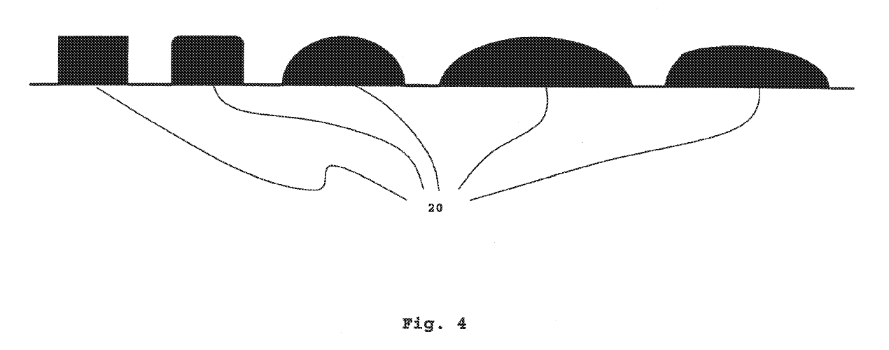

The protruding elements may have any shape, e.g. spherical, rectangular, oval, triangular, or longitudinal (i.e. along the long side/lengthwise of the cover plate). Preferably, they are pherical, rectangular, oval or longitudinal. The longitudinal protruding element may have any shape as long as it follows the cover plate lengthwise. FIG. 4 illustrates suitable shapes of protruding elements. Different shapes of protruding elements may be combined. Preferred protruding elements are elongated ribs. Preferably the cover plate is provided with at least two elongated ribs; more preferably at least three and most preferably at least four. These elements may be positioned parallel to each other. The length of the elongated rib(s) is preferably between 1 mm and 25 cm, more preferably between 5 mm and 15 cm and most preferably between 10 mm and 10 cm. The length may be at least the sum of the length of 10A and 10B. The height of the elongated rib(s) is preferably at least 0.1 mm and at most 50 mm, more preferably between 0.1 mm and 10 mm and most preferably between 1 mm and 5 mm. The elongated rib(s) may be oriented at an angle relative to the processing direction. Such elongated ribs may be parallel to the processing direction of the plate, indicated by the arrow (23) in FIG.3, but are more preferably oriented at an angle relative to the processing direction. Said angle (α in FIG. 3b) is for example 1 to 45° preferably 5 to 35° and most preferably 10 to 25° relative to the processing direction. Alternatively, the angle α may have a different value for one or more ribs, or in other words the ribs may be not fully parallel relative to each other.

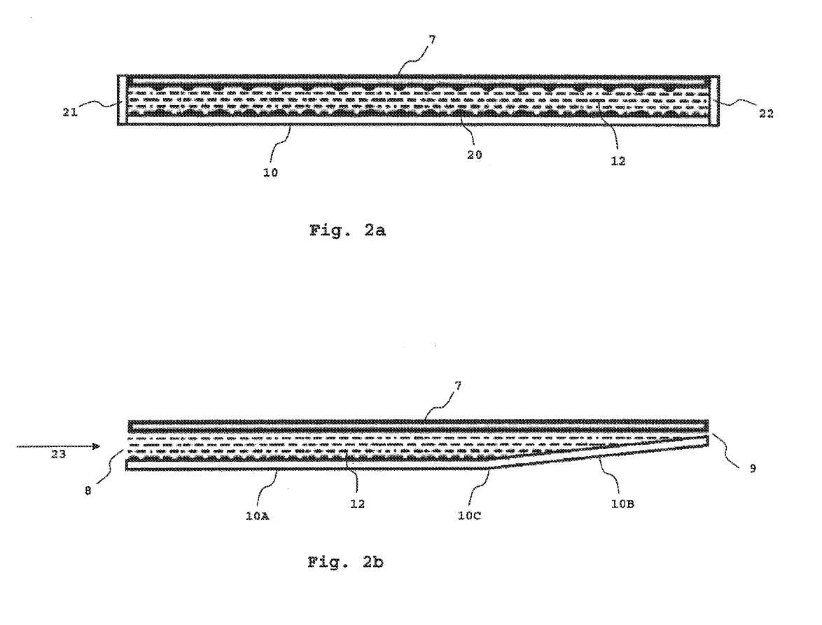

In the preferred embodiment of FIG. 2a, the protruding elements (20) have a trapezoidal cross-section with a rounded top. The height of the protruding elements—measured at the heighest part in case of spherical, round or oval shapes—is preferably at least 0.1 mm and at most 50 mm, more preferably between 1 mm and 10 mm and most preferably between 1 mm and 5 mm.

These elements may be positioned for example ad random, grouped in a matrix, or along parallel lines. Such lines may be parallel to the processing direction of the plate but are more preferably oriented at an angle relative to the processing direction. Said angle (α; as illustrated for elongated ribs in FIG. 3b) is for example 1 to 45° preferably 5 to 35° and most preferably 10 to 25° relative to the processing direction. Alternatively, the angle α may have a different value for one or more lines, or in other words the lines may be not fully parallel relative to each other. The length of the lines is preferably between 1 mm and 25 cm, more preferably between 5 mm and 15 cm and most preferably between 10 mm and 10 cm.

The protruding elements may be made from metal, fiber, and/or other flexible/ductile materials. The relief may be extruded, oriented, expanded, woven or tubular and can be made from polypropylene, polyethylene, nylon, PVC or PTFE. A metal relief may be woven, knitted, welded, expanded, photo-chemically etched or electroformed from steel or other metals.

As described above, the development solution is preferably regenerated by means of an inlet that supplies regenerator liquid, which may be water and/or replenishment solution, to development unit (5) and/or development cavity (6). Other well known elements of the regenerator system are not shown in the Figures, such as a supply tank for holding replenishment solution; a pump and the necessary pipes to supply the regenerator liquid to the development unit (5) and/or development cavity (6).

### Preferred Processing Apparatus: Supply of Developer by Nozzles

In order to provide sufficient turbulence within the development unit, the developer is preferably applied onto the printing plate by means of nozzles which spray or jet a flow of developer on the surface of the plate. The nozzles may be configured as an array of nozzles, e.g. an array of holes in a spray bar or an array of jet nozzles in an inkjet head, e.g. a valve-jet head.

The use of nozzles is especially suitable for the embodiment wherein the development unit comprises a development cavity as described above. In that embodiment, the nozzles may be integrated in a sidewall or in both sidewalls of the development cavity so as to discharge development solution transversely over the coating of the plate. In the alternative, the nozzles may be present in the bottom or the cover plate, depending which of both is facing the image recording layer of the printing plate. Combined embodiments wherein nozzles are integrated in one or both sidewalls as well as in the bottom and/or the cover plate are also within the scope of this invention.

The developer is preferably supplied by the nozzles as a pressurized flow over the surface area of the plate such that successive target areas of the plate are dynamically and uniformly flooded with development solution. The nozzle streams of development solution can be tuned with respect to direction, shape, overlap, and surface turbulence. Although the plate target area preferably experiences a continuous turbulent flooding, the supply through the nozzles can also be applied in consecutive pulses. Dissolution of the soluble coating regions is thereby achieved quickly and uniformly by providing a flow of developer liquid which causes turbulence and which is constantly displaced and replaced.

At sufficient volumetric flow rate, the development solution is constantly displaced at the surface of the plate during the development dwell time, whereby no boundary layer forms on and travels with the plate and each unit volume of coating is rapidly and uniformly processed. Preferably, depending on the speed at which the plate travels through the development unit, a turbulent flow of development solution is applied for a short dwell time onto each unit area of the coated plate; for example, at a speed between 0.5 and 5 m/min, a dwell time of less than about 30 seconds, more preferably a dwell time between 5 and 25 seconds and most preferably a dwell time between 8 and 15 seconds. These figures are only a practical guideline and may be outside these ranges.

The use of brushes is not required in order to obtain fast and efficient development of the plates. In a preferred embodiment, the development cavity does not contain any brushes whereby the risk of scratches on the image areas and/or maintenance (cleaning) of the brushes are eliminated.

Suitable spray nozzles are commercially available in many sizes and configurations, e.g. from Spraying Systems Co. (Wheaton, Ill., USA). Important parameters of the spray nozzles are the flow rate, the spray pressure, the drop size, the spray pattern and the spray nozzle alignment. Useful spray pressures are in the range of 1 to 5 bar, more preferably from 1.5 to 2.5 bar. A preferred spray pattern is a tapered-edge flat pattern because it can provide a uniform coverage over the entire plate area as a result of overlapping distributions. The angle of the spray cone and the spray distance between the spray nozzle and the plate define the target area on the plate. The nozzles may have a spray angle from 5° to 170°, the larger angle producing a large target area for a given spray distance. The nozzle target area on the plate depends on the spray angle and the spray distance and may be up to 15 cm, which can be achieved by a nozzle having e.g. a spray angle of 110° and a spray distance of 5 cm. However a smaller target area is preferred, e.g. less than 5 cm which may be achieved by a nozzle N with a spray angle of 50° and a 5 cm spray distance or 30° and 10 cm respectively. Suitable drop sizes of the spray are from less than 1 mm, e.g. 100 μm (achieved by so-called atomizing nozzles), up to a few mm, e.g. from 1 to 5 mm, preferably from 1 to 2 mm. The drop size is mainly determined by the spray pressure and of course the properties of the developer liquid.

The spray nozzles are preferably made of a material which is resistant to the developer liquid and provides a long wear life, e.g. stainless steel, a ceramic or a carbide. More information about spray nozzles can be found in e.g. the books “Industrial Sprays and Atomization”, Springer, 1st edition (Sep. 17, 2002) and “Handbook of Atomization and Sprays”, Springer, 2011.

Especially when high-resolution nozzles, i.e. nozzles with a very small target area on the plate such as the nozzles of an inkjet head, are used, more intelligence can be built into the apparatus by supplying image data from the platesetter or the workflow software to the digital controller of the apparatus of the present invention. Image-controlled development can be achieved in the apparatus of the present invention by a digital controller wherein the average dot coverage at the target area of each nozzle, which is a portion of the image, is calculated and which adjusts the volume of developer deposited on that target area in accordance with said average dot coverage. In such embodiment, no developer is deposited on “full-black” portions of the image, i.e. portions which consist entirely of printing areas, and a sufficient amount of developer is deposited on the gray and white portions of the image, wherein said amount is made proportional to the average dot coverage of said gray and white portions. More details concerning suitable nozzles can be found in EP 2 775 351 (for example [0034] to [0049]).

### Inlet Opening for Sucking in the Development Solution

The development solution is preferably at least partly sucked in from the area under and/or near the exit rollers in the development unit. Preferably, the development solution is sucked in via at least one inlet opening in the development unit near the exit roller pair (11B). In the area at the exit roller pair (11B), compared to the other parts of the development unit, the developer is more exhausted and contaminated with for example undissolved components which may result in deposit on the exit and/or other rollers and/or build-up on heater elements, and/or possible adherence of sludge on the printing plate which may impair the images formed thereon. Therefore, it is preferred to create turbulence at that area whereby the development solution may be, at least partly, homogenized. Combined with at least one inlet opening for injecting or jetting the development solution (see below), this homogenization is even further improved.

### Inlet Opening for Injecting or Jetting the Development Solution

The development solution which is sucked in, is preferably jetted or injected through at least one inlet opening into the development unit. Preferably, the at least one inlet opening for jetting or injecting the development solution is integrated in the development unit and/or cavity. The at least one inlet opening for injecting the developing solution is preferably integrated in at least one sidewall (21 and 22) of the development cavity whereby the development solution is injected transversely over the coating of the plate, preferably without air contact. Most preferably, the at least one inlet opening for injecting the developing solution is present in the first half (relative to the entry aperture (8)) of the total length of the at least one sidewall (21 and 22) of the development cavity. Alternatively, the at least one inlet opening for injecting the developing solution may be present in the bottom and/or the cover plate. The at least one inlet opening is preferably integrated in the cover plate. This configuration has the advantage that the developer is equally applied over the surface of the coating in comparison with inlet openings in the side of the development unit where the development solution is applied from one side.

In an alternative preferred embodiment, the development solution which is sucked in, is jetted or injected through at least one inlet opening in the development unit near the exit roller pairs (11B). Preferably, the at least one inlet opening is integrated in the side walls encompassing the exit rollers (11B). More preferably, the at least one inlet opening is present in the sidewalls (27A) and (27B). As explained above, in the area of the exit rollers (11B) the developer is more exhausted and/or contaminated and it is preferred to create turbulence to homogenize the developer liquid. Combined with at least one inlet opening for sucking in the development solution in the same area i.e. in the area of the exit roller pair (11B) (see above), this homogenization may be even further improved.

The at least one inlet opening may be integrated in both the sidewall(s) and the bottom and/or cover plate.

Also preferred is that the at least one inlet opening is present in one or more spray bars which may be integrated in the development unit and/or cavity, for example in the sidewalls, bottom or cover plate as discussed above. Preferably, the spray bar(s) is positioned in the development unit near the exit roller pair (11B). More preferably, the spary bar(s) is positioned parallel to the exit roller pair (11B).

Preferred Processing Apparatus: Water Rinse and/or Gumming Section

The processing apparatus contains following the development section as described above, a water rinse section provided with at least one, preferably at least two spray nozzles capable of spraying water at both the front side and the backside of the plate and/or a gumming section provided with at least one spray nozzle capable of spraying gum at the front side and the backside of the plates. The processing apparatus may contain following the development section two or three water rinse sections.

In a preferred embodiment, the development section of the processing apparatus is followed by a gumming section which contains at least two gumming units which are configured as a cascade configuration, which means that the gum solution overflows from the second gumming unit into the first gumming unit. At least one of these gumming units is capable to provide gum to both the front side and the backside of the plate. Additional gumming units may be used, but only two gumming units are preferred. Preferably, the first gumming unit does not allow overflow to the development section.

The gum solution is applied to the printing plate by a spraying, jetting, dipping or coating technique, including spin coating, roll coating, slot coating or gravure coating. The use of spray or (valve) jet nozzles is preferred. All features of the nozzles described above for supplying development solution equally apply to preferred embodiments for depositing gum on the plate, possibly in accordance with the plate area or even with the image data of the plate, as described in EP 2 775 351.

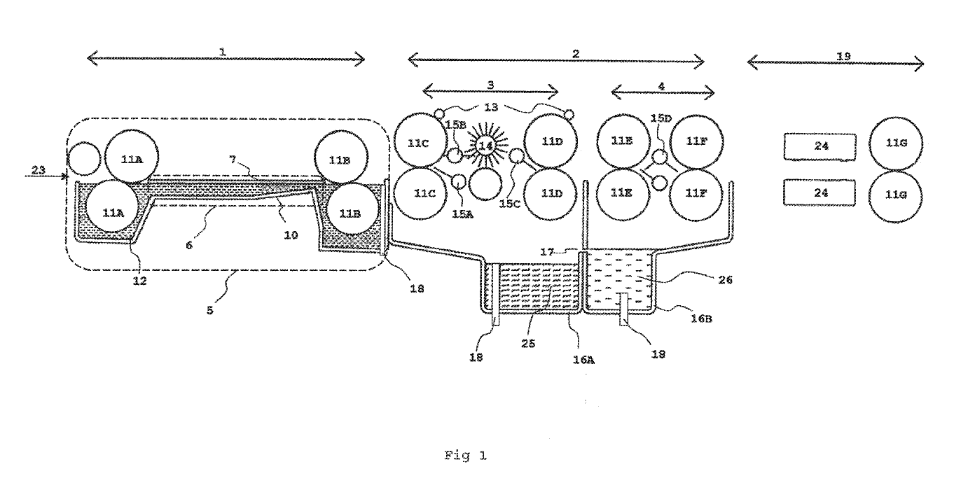

In the preferred embodiment of FIG. 1, the nip rollers (11C, 11D) of the first gumming unit are provided with a scavenger roller (13) to prevent contamination of gum into the developer unit. Three spray bars are provided in the first gumming unit: one bar (15A) which sprays gum solution to the backside of the plate and/or to the nip of the nip rollers, one bar (15B) which is capable of spraying gum both onto the nip of the roller pair (11C) and onto the brush (14) which is configured to apply gum onto the image of the plate, and one bar (15C) which sprays gum towards the nip of the roller pair (11D). Preferably, the bar(s) for spraying the first gum solution, more preferably bars (15B) and (15C) are in a so-called jog-mode, i.e. gum is provided on a regular basis even when no plate is present in the gumming unit in order to prevent stickyness of the nip rollers and/or brush. Preferably, the nip rollers are engaged on a regular basis; even when no plate passes. The second gumming unit further includes a spray bar (15D) which is capable of keeping both nip rollers in the second unit (11E, 11F) wet and which provides a finishing layer onto the surface of the plate. The second gumming unit further includes a spray bar (15E) which sprays gum solution to the backside of the plate and/or to the nip of the nip rollers. These spray bars may also be in the jog-mode.

As described above, the second gum solution is preferably regenerated by means of an inlet that supplies regenerator liquid, which may be water, optionally diluted fresh gum and/or replenishment solution, to the second gumming unit, e.g. to the sump (16B). Other well known elements of the regenerator system are not shown in the Figures, such as a supply tank for holding fresh gum solution, water or replenishment solution; a pump and the necessary pipes to supply the regenerator liquid to the second gumming unit. Also the first gum solution may be regenerated, either by the same or an analogous regeneration system as used for the second gum solution. The first gum solution may also be regenerated by actively pumping gum solution from the second to the first gumming unit.

### Preferred Processing Apparatus: Drying Section

After the final gum has been applied, the plate is preferably immediately conveyed to a drying section (19) which is preferably integrated into the apparatus. Drying can be achieved by means (24) for emitting hot air, infrared and/or microwave radiation, and other methods generally known in the art. The plate may then be mounted on the plate cylinder of a printing press and the printing process may be started.

### Lithographic Printing Plate Materials

Any type of heat- and/or light-sensitive plate materials can be processed according to the methods and with the apparatus of the present invention. The lithographic printing plate material can be negative- or positive-working, i.e. can form ink-accepting areas at exposed or at non-exposed areas respectively. Below, suitable examples of heat- and light-sensitive coatings are discussed.

### Support

The preferred support of the lithographic printing plate material used in the present invention has a hydrophilic surface or is provided with a hydrophilic layer at the front side of the support. A particularly preferred lithographic support is a grained and anodized aluminum support, more preferably aluminum grained by electrochemical graining in a solution comprising nitric acid and/or hydrochloric acid and then electrochemically anodized in a solution comprising phosphoric acid and/or sulphuric acid.

### Coating Compositions

Any type of heat- and/or light-sensitive plate materials can be provided onto the support. Preferred materials are positive- or negative-working plate materials which require alkaline processing. Positive-working heat-sensitive materials are highly preferred.

Negative-working plates typically form an image by light- or heat-induced chemical crosslinking or polymerization of a photopolymer coating or by physical insolubilization due to heat-induced coalescence, fusing or melting of thermoplastic polymer particles. Specially designed negative-working plates allow processing without hazardous developer, i.e. of high pH or containing a large amount of organic solvents, e.g. by using gums or a fountain solution of neutral or low pH. More details about the composition of and methods of making negative-working plate precursors are described in e.g. US2009/0197206, EP 2 153 279, WO2006/048443, EP 1 349 006, EP 1 614 538, EP 931 647, WO2002/21215 and EP 1 817 166.

These printing plate precursors can be sensitized with blue, green or red light (i.e. wavelength range between 450 and 750 nm), with violet light (i.e. wavelength range between 350 and 450 nm) or with infrared light (i.e. wavelength range between 750 and 1500 nm) using for example an Ar laser (488 nm) or a FD-YAG laser (532 nm), a semiconductor laser InGaN (350 to 450 nm), an infrared laser diode (830 nm) or a Nd-YAG laser (1064 nm).

In positive-working plates, the higher dissolution of non-printing areas is typically due to a kinetic differentiation of the dissolution process: the exposed areas dissolve more quickly in the developer than the non-exposed areas, so that a lithographic image is obtained after a typical development time of 15 to 30 seconds.

A highly preferred heat-sensitive printing plate precursor is positive-working and includes a coating which is based on heat-induced solubilization of an oleophilic resin. The oleophilic resin is preferably a polymer that is soluble in an aqueous developer, more preferably an aqueous alkaline development solution with a pH between 7.5 and 14. Preferred polymers are phenolic resins e.g. novolac, resoles, polyvinyl phenols and carboxy substituted polymers. Typical examples of these polymers are described in DE-A-4007428, DE-A-4027301 and DE-A-4445820. The coating preferably contains at least one layer which includes the phenolic resin(s). This layer is also referred to as “the imaging layer” or the first layer. The amount of phenolic resin present in the coating is preferably at least 50% by weight, preferably at least 80% by weight relative to the total weight of all the components present in the imaging layer. The oleophilic resin may also be mixed with or replaced by other polymers such as polymers including a urethane group and/or poly(vinyl acetal) resins. Suitable poly(vinyl acetal) resins which are added in order to improve the abrasion resistance of the coating are described in U.S. Pat. No. 5,262,270; U.S. Pat. No. 5,169,897; U.S. Pat. No. 5,534,381; U.S. Pat. No. 6,458,511; U.S. Pat. No. 6,541,181; U.S. Pat. No. 6,087,066; U.S. Pat. No. 6,270,938; WO 2001/9682; EP 1 162 209; U.S. Pat. No. 6,596,460; U.S. Pat. No. 6,596,460; U.S. Pat. No. 6,458,503; U.S. Pat. No. 6,783,913; U.S. Pat. No. 6,818,378; U.S. Pat. No. 6,596,456; WO 2002/73315; WO 2002/96961; U.S. Pat. No. 6,818,378; WO 2003/79113; WO 2004/20484; WO 2004/81662; EP 1 627 732; WO 2007/17162; WO 2008/103258; U.S. Pat. No. 6,087,066; U.S. Pat. No. 6,255,033; WO 2009/5582; WO 2009/85093; WO 2001/09682; US 2009/4599; WO 2009/99518; US 2006/130689; US 2003/166750; U.S. Pat. No. 5,330,877; US 2004/81662; US 2005/3296; EP 1 627 732; WO 2007/3030; US 2009/0291387; US 2010/47723 and US 2011/0059399.

The coating may further comprise a second layer that comprises one or more other binder(s) which is insoluble in water and soluble in an alkaline solution such as an organic polymer which has acidic groups with a pKa of less than 13 to ensure that the layer is soluble or at least swellable in aqueous alkaline developers. This layer is located between the layer described above comprising the oleophilic resin i.e. the imaging layer, and the hydrophilic support. This layer is also referred to as “the second layer”. The binder may be selected from a polyester resin, a polyamide resin, an epoxy resin, an acrylic resin, a methacrylic resin, a styrene based resin, a polyurethane resin or a polyurea resin. The binder may have one or more functional groups. The functional group(s) can be selected from the list of
(I) a sulfonamide group such as —NR—SO₂—, —SO₂—NR— or —SO₂—NR′R″ wherein R and R′ independently represent hydrogen or an optionally substituted hydrocarbon group such as an optionally substituted alkyl, aryl or heteroaryl group; more details concerning these polymers can be found in EP 2 159 049;
(II) a sulfonamide group including an acid hydrogen atom such as —SO₂—NH—CO— or —SO₂—NH—SO₂— as for example disclosed in U.S. Pat. No. 6,573,022 and/or EP 909 68(of 5)7; suitable examples of these compounds include for example N-(p-toluenesulfonyl) methacrylamide and N-(p-toluenesulfonyl) acrylamide;
(III) an urea group such as —NH—CO—NH—, more details concerning these polymers can be found in WO 01/96119;
(IV) a star polymer in which at least three polymer chains are bonded to a core as described in EP 2 497 639;
(V) a carboxylic acid group;
(VI) a nitrile group;
(VII) a sulfonic acid group;
(VIII) a phosphoric acid group and/or
(IX) a urethane group.

More details about the composition of and methods of making positive-working heat-sensitive plate precursors are described in e.g. US2009/0197206, EP823327A, WO97/39894, EP864420A, WO99/63407, EP1826001A, EP901902A, EP909657A and EP1159133A.

The printing plate precursor can be exposed to infrared light by means of e.g. LEDs or a laser, which is preferably converted into heat by an infrared light absorbing agent which may be a dye or pigment having an absorption maximum in the infrared wavelength range. Most preferably, the light used for the exposure is a laser emitting near infrared light having a wavelength in the range from about 750 to about 1500 nm, more preferably 750 to 1100 nm, such as a semiconductor laser diode, a Nd:YAG or a Nd:YLF laser. The required laser power depends on the sensitivity of the plate precursor, the pixel dwell time of the laser beam, which is determined by the spot diameter (typical value of modern plate-setters at 1/e² of maximum intensity: 5-25 μm), the scan speed and the resolution of the exposure apparatus (i.e. the number of addressable pixels per unit of linear distance, often expressed in dots per inch or dpi; typical value: 1000-4000 dpi).

Any coating method can be used for applying one or more coating solutions to the hydrophilic surface of the support. The multi-layer coating can be applied by coating/drying each layer consecutively or by the simultaneous coating of several coating solutions at once. In the drying step, the volatile solvents are removed from the coating until the coating is self-supporting and dry to the touch. However it is not necessary (and may not even be possible) to remove all the solvent in the drying step. Indeed the residual solvent content may be regarded as an additional composition variable by means of which the composition may be optimized. Drying is typically carried out by blowing hot air onto the coating, typically at a temperature of at least 70° C., suitably 80-150° C. and especially 90-140° C. Also infrared lamps can be used. The drying time may typically be 15-600 seconds.

### Lithographic Printing Plate

According to the present invention, there is also provided a heat and/or light sensitive printing plate which comprises:
a support as described above;
a heat and/or light sensitive lithographic image present at the front side of said support; and
a hydrophilic layer including a gum solution including film-forming hydrophilic polymers and/or surfactants provided at the backside of said support.

The heat and/or light sensitive lithographic image is obtained after development of a heat and/or light sensitive coating as described above. The hydrophilic layer at the back side of the support is obtained by the application of a gum solution as described above. The layer may subsequently be dried. The dry coating weight of the hydrophilic layer that remains on the front side and/or the backside of the plate after treatment with the gum solution preferably comprises between 0.01 and 20 g/m² of the surface protective compound. Alternatively, the dry coating weight is preferably between 0.02 and 5 g/m², more preferably between 0.03 and 1 g/m², and most preferably between 0.05 and 0.5 g/m². It is an advantage of the present invention that with the hydrophilic layer at the back side of the support, the friction coefficient of the plates in contact with each other or with any other material e.g. hands of a printer, can be controlled to minimize damaging of the lithographic image during handling.

1-15. (canceled)

16. A method for processing a lithographic printing plate material including a support, a front side provided with an imaging layer, and a backside opposite to the front side, the method comprising the steps of:
treating the plate material with an alkaline development solution; and
treating the plate material with an aqueous liquid; wherein
the aqueous liquid is sprayed on both the front side and the backside of the plate material.

17. The method according to claim 16, wherein the aqueous liquid consists of water.

18. The method according to claim 16, further comprising the step of:
after the step of treating the plate material with the aqueous liquid, treating the plate material with a gumming liquid on both the front side and the backside of the plate material.

19. The method according to claim 16, wherein the aqueous liquid defines a first gum solution.

20. The method according to claim 19, further comprising the step of:
after the step of treating the plate material with the aqueous liquid, treating the plate material with a second gum solution; wherein
the second gum solution overflows into the first gum solution.

21. The method according to claim 20, wherein the second gum solution is applied to both the front side and the backside of the plate material.

22. The method according to claim 19, wherein the method comprises no rinsing step between the step of treating the plate material with the alkaline development solution and the step of treating the plate material with the aqueous liquid.

23. The method according to claim 16, wherein the alkaline development solution has a pH of at least 10.

24. The method according to claim 19, wherein the first gum solution has a pH below 10.

25. The method according to claim 19, wherein the first gum solution has a pH from 0 to 8.

26. An apparatus for processing a lithographic printing plate material including a front side provided with an imaging layer and a backside opposite to the front side, the apparatus comprising:
a development unit;
a first nozzle that sprays an aqueous liquid on the front side of the plate material; and
a second nozzle that sprays the aqueous liquid on the backside of the plate material.

27. The apparatus according to claim 26, wherein each of the first nozzle and the second nozzle are provided in a first gumming unit, and the aqueous liquid is a gum solution.

28. The apparatus according to claim 27, further comprising a second gumming unit; wherein
the first gumming unit and the second gumming unit are connected such that the gum solution overflows from the second gumming unit into the first gumming unit.

29. A heat and/or light sensitive printing plate comprising:
a support; and
a lithographic image provided on a front side of the support; wherein
a backside of the support includes a hydrophilic layer including a gum solution including film-forming hydrophilic polymers and/or surfactants.

30. The heat and/or light sensitive printing plate according to claim 29, wherein the hydrophilic layer includes between 0.01 g/m² and 20 g/m² of the gum solution including the film-forming hydrophilic polymers and/or the surfactants.
